(19) United States
(12) Patent Application Publication
(10) Pub. No.: US 2026/0082496 A1
(43) Pub. Date: Mar. 19, 2026

(54) Electronic Devices with Crack-Resistant Cover Layers

(71) Applicant: Apple Inc., Cupertino, CA (US)

(72) Inventor: Christopher D. Jones, Los Gatos, CA (US)

(21) Appl. No.: 19/236,514

(22) Filed: Jun. 12, 2025

Related U.S. Application Data
(60) Provisional application No. 63/695,686, filed on Sep. 17, 2024.

(51) Int. Cl. H05K 5/03

(52) U.S. Cl. CPC H05K 5/03

(57) ABSTRACT

A foldable electronic device may include a flexible display panel and a display cover layer that fold along a bend axis. The display cover layer may be formed from one or more glass layers. For example, a thin glass layer may form an outer surface of the display and may extend across the bend axis. The glass layer may exhibit a crack initiation load of at least 10 kgf to help prevent sharp objects from causing median cracks in the cover layer that might lead to failure. An ion exchange process may be used to impart regions of compressive stress in the glass and to further increase the force required to cause failure in the cover layer. To allow the glass to bend, the glass may have a bendable region with a thickness of 200 microns or less.

This application claims the benefit of U.S. provisional patent application No. 63/695,686, filed Sep. 17, 2024, which is hereby incorporated by reference herein in its entirety.

### FIELD

This relates generally to electronic devices, and, more particularly, to electronic devices with displays.

### BACKGROUND

Electronic devices often have displays. Portability may be a concern for some devices, which tends to limit available real estate for displays.

### SUMMARY

An electronic device may be provided with a foldable housing that allows the device to fold and unfold about a bend axis. A flexible display may be mounted in the foldable housing. The flexible display may have an array of pixels forming a display panel. The display panel may be configured to bend along the bend axis as the device is folded.

The display may include a display cover layer such as a cover glass. The cover glass may overlap the display panel and may include first and second portions joined by a bendable portion. The bendable portion may have a reduced thickness relative to the first and second portions, or the glass may have a uniform thickness across the first and second portions and the bendable region. A groove may be formed in the bendable region to facilitate bending. The groove may be filled with a transparent polymer.

The cover layer may include a thin glass layer that forms an exposed, bare glass surface on the display of the electronic device. The glass layer may exhibit a crack initiation load of at least 10 kgf to help prevent sharp objects from causing median cracks in the cover layer that might lead to failure. An ion exchange process may be used to impart regions of compressive stress in the glass and to further increase the force required to cause failure in the cover layer. The high cracking resistance of the cover glass may allow the cover glass to be used to protect the display without requiring a protective polymer layer on the outer surface of the cover glass. To facilitate bending, the glass may have a bendable region with a thickness of 200 microns or less.

### BRIEF DESCRIPTION OF THE DRAWINGS

FIG. 1 is a schematic diagram of an illustrative electronic device in accordance with some embodiments.

FIG. 2 is a perspective view of an illustrative electronic device with a display in accordance with some embodiments.

FIG. 3 is a side view of an illustrative electronic device in accordance with some embodiments.

FIG. 4 is a side view of an illustrative cover layer having a hinge region with a thickness that is less than the thickness of other portions of the cover layer in accordance with some embodiments.

FIG. 5 is a side view of an illustrative display having a cover layer that includes a layer of glass that exhibits a high crack initiation load and that forms an exposed, bare glass outer surface of the display in accordance with some embodiments.

FIG. 6 is a side view of an illustrative cover layer that includes a layer of glass that exhibits a high crack initiation load and that has a reduced thickness in a hinge region in accordance with some embodiments.

FIG. 7 is a side view of an illustrative layer of glass that exhibits a high crack initiation load during a Vickers indentation cracking test in accordance with some embodiments.

FIG. 8 is a graph showing how different glass compositions exhibit different cracking thresholds in accordance with some embodiments.

FIG. 9 is a graph showing how different glass compositions and ion exchange conditions result in different force-to-failure values in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., diodes formed from crystalline semiconductor dies).

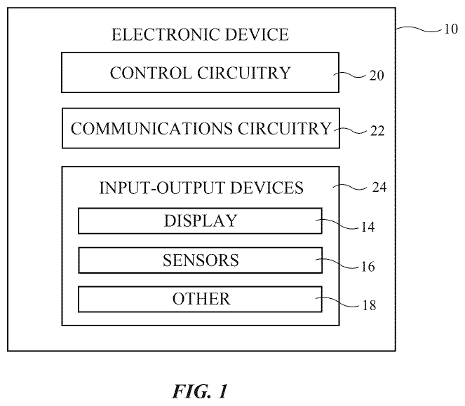

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display.

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

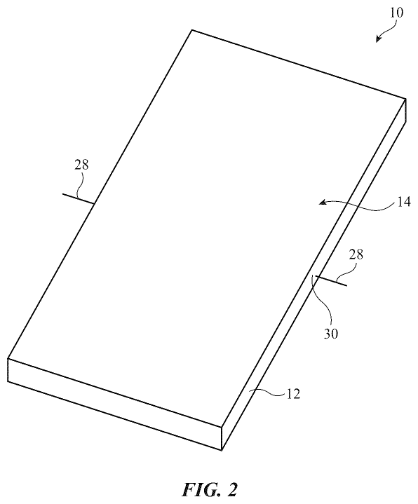

FIG. 2 is a perspective view of electronic device 10 in an illustrative configuration in which device 10 is a portable electronic device such as a cellular telephone or tablet computer. As shown in FIG. 2, device 10 may have a display such as display 14. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometimes be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Housing 12 may have flexible structures (e.g., bendable housing wall structures) and/or hinge structures such as hinge 30. Hinge 30 may have a hinge axis aligned with device bend axis 28. Hinge 30 and/or flexible housing structures that overlap bend axis 28 may allow housing 12 to bend about bend axis 28. For example, housing 12 may have a first portion on one side of bend axis 28 and a second portion on an opposing side of bend axis 28 and these two housing portions may be coupled by hinge 30 for rotational motion about axis 28.

As housing 12 is bent about bend axis 28, the flexibility of display 14 allows display 14 to bend about axis 28. In an illustrative configuration, housing 12 and display 14 may bend by 180°. This allows display 14 to be folded back on itself (with first and second outwardly-facing portions of display 14 facing each other). The ability to place device 10 in a folded configuration in this way may help make device 10 compact so that device 10 can be stored efficiently. When it is desired to view images on display 14, device 10 may be unfolded about axis 28 to place device 10 in the unfolded configuration of FIG. 2. This allows display 14 to lie flat and allows a user to view flat images on display 14. The ability to fold display 14 onto itself allows device 10 to exhibit an inwardly folding behavior. Display 14 may be sufficiently flexible to allow device 10 to be folded outwardly and/or inwardly.

Device 10 of FIG. 2 has a rectangular outline (rectangular periphery) with four corners. As shown in FIG. 2, a first pair of parallel edges (e.g., the left and right edges of device 10 in the example of FIG. 2) may be longer than a second pair of parallel edges (e.g., the upper and lower edges of device 10 of FIG. 2) that are oriented at right angles to the first pair of parallel edges. In this type of configuration, housing 12 is elongated along a longitudinal axis that is perpendicular to bend axis 28. Housing 12 may have other shapes, if desired (e.g., shapes in which housing 12 has a longitudinal axis that extends parallel to bend axis 28). With an arrangement of the type shown in FIG. 2, the length of device 10 along its longitudinal axis may be reduced by folding device 10 about axis 28.

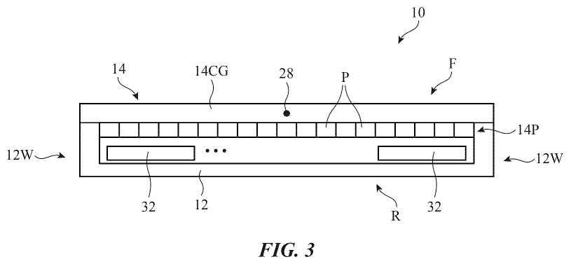

FIG. 3 is a cross-sectional side view of an illustrative foldable electronic device. Device 10 of FIG. 3 may bend about bend axis 28. Bend axis 28 may be aligned with display cover layer 14CG or other structures in device 10. For example, bend axis 28 may pass through a portion of display cover layer 14CG or may be located above or below layer 14CG.

As shown in FIG. 3, display 14 includes an array of pixels P forming display panel 14P under an inwardly facing surface of display cover layer 14CG. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures.

Display cover layer 14CG may be formed from polymer, glass, crystalline materials such as sapphire, other materials, and/or combinations of these materials. To enhance flexibility, a portion of layer 14CG that overlaps bend axis 28 may be locally thinned (e.g., this portion may be thinned relative to portions of layer 14CG that do not overlap bend axis 28). The thickness of layer 14CG (e.g., the non-thinned portions of layer 14CG) may be 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness.

In the example of FIG. 3, housing 12 has a portion on rear face R that forms a rear housing wall and has side portions forming sidewalls 12W. The rear housing wall of housing 12 may form a support layer for components in device 10. Housing 12 may also have one or more interior supporting layers (e.g., frame structures such as an optional midplate, etc.). These interior supporting layers and the rear housing wall may have first and second portions that are coupled to opposing sides of a hinge that is aligned with bend axis 28 (see, e.g., hinge 30 of FIG. 2) or may be sufficiently flexible to bend around bend axis 28.

Electrical components 32 may be mounted in the interior of device 10 (e.g., between display 14 and the rear of housing 12. Components 32 may include circuitry of the type shown in FIG. 1 (e.g., control circuitry 20, communications circuitry 22, input-output devices 24, batteries, etc.). Display 14 may be mounted on front face F of device 10. When device 10 is folded about axis 28, display cover layer 14CG, display panel 14P, and the other structures of device 10 that overlap bend axis 28 may flex and bend to accommodate folding.

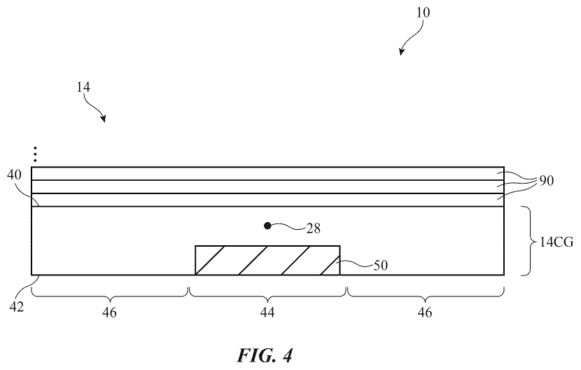

In some arrangements, the outer and/or inner surfaces of display cover layer 14GC may be provided with coatings. These coatings may include, for example, antireflection coatings, anti-scratch coatings, anti-smudge coatings, and/or other coating layers. Consider, as an example, the cross-sectional side view of display cover layer 14CG of FIG. 4. As shown in FIG. 4, display cover layer 14CG may have an outer surface (outwardly facing surface) such as surface 40 and an opposing inner surface (inwardly facing surface) such as surface 42. A strip-shaped region of display cover layer 14CG that overlaps and runs parallel to bend axis 28 may have a locally reduced thickness (e.g., a groove or other recess that runs parallel to bend axis 28 may be formed in layer 14CG to form locally reduced thickness portion 44 of layer 14CG). Locally reduced thickness portion 44 of layer 14CG may be thinner than other portions of layer 14CG such as portions 46 (which may be, for example, planar glass layer portions of layer 14CG). The presence of reduced thickness portion 44 in display cover layer 14CG may facilitate bending of display cover layer 14CG about bend axis 28.

To help planarize inner surface 42 and thereby facilitate mounting of display panel 14P against inner surface 42 (e.g., with a layer of adhesive), the elongated recess (groove) in the inner surface of layer 14CG that forms thinned portion 44 may be filled with a polymer such as polymer 50. Polymer 50 may be sufficiently flexible to bend about bend axis 28 when device 10 is opened and closed. The refractive index of polymer 50 may be matched to that of display cover layer 14CG to help minimize light reflections (e.g., by incorporating inorganic nanoparticles in polymer 50). For example, at a wavelength of 500 nm, the refractive index of polymer 50 may differ from that of layer 14CG by less than 0.15, less than 0.1, or less than 0.05 (as examples).

Coating layers 90 may optionally be formed on outer surface 40. Coating layers 90 may include, for example, anti-scratch layers (sometimes referred to as hard coats), protective polymer layers, anti-smudge layers, anti-fog layers, antireflection layers, anti-static layers, adhesion layers, and/or other coatings. In some configurations, each of these functions may be implemented using a separate respective coating layer. In other configurations, a single layer may serve multiple functions. In general, coatings such as coatings 90 may be formed on outer surface 40 and/or inner surface 42. In the illustrative configuration of FIG. 4, coatings 90 are formed on outer surface 40.

Coatings 90 may be provided in any suitable order. As one example, the lowermost coating of coatings 90 (e.g., a coating layer formed directly on surface 40 of FIG. 4) may be a hard coat or other anti-scratch layer that helps prevent scratches that could damage layer 14CG. An antireflection coating may be formed on top of the anti-scratch layer. The antireflection layer may be a thin-film interference filter antireflection coating containing a stack of thin-film layers such as dielectric sublayers of alternating refractive index. One of the thin-film layers may be a conductive layer such as a transparent semiconductor layer (e.g., an indium tin oxide layer) that serves as an antistatic layer. An anti-smudge coating or anti-fog coating may be formed on top of the antireflection layer. Anti-smudge coatings (e.g., hydrophobic polymer coatings) may help reduce fingerprints and other undesired marks on the surfaces of display 14. An example of an anti-smudge coating is a fluoropolymer coating (e.g., a fluoropolymer formed from evaporated perfluoropolyether) that serves as an oleophobic layer. Fluoropolymers can be adhered to underlying coating layers using an intervening adhesion layer.

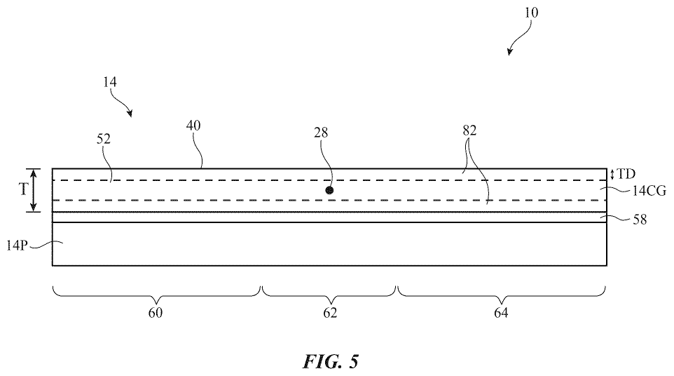

In some configurations, one or more of coatings 90 such as a protective polymer layer may be omitted and the outermost surface of display 14 may be formed from bare glass. This type of arrangement is illustrated in FIG. 5.

As shown in FIG. 5, display 14 may include display panel 14P and cover layer 14CG. Cover layer 14CG may overlap display panel 14P and may be attached to display panel 14P using adhesive such as adhesive 58. Display 14 may include first portion 60 and second portion 64 joined by bendable portion 62. Bendable portion 62 overlaps bend axis 28 and is configured to bend as device 10 is folded and unfolded. As device 10 is folded and unfolded and portion 62 bends, first portion 60 of display 14 may rotate relative to second portion 64. If desired, first portion 60 and second portion 64 of display panel 14P and cover layer 14CG may remain planar or substantially planar as device 10 is folded and unfolded, while portion 62 of display panel 14P and cover layer 14CG may bend and flex as device 10 is moved between folded and unfolded configurations.

Cover layer 14CG may include one or more transparent layers such as outer transparent layer 52. Transparent layer 52 may be formed from glass, polymer, sapphire, and/or any other suitable material. Arrangements in which layer 52 is formed from glass are sometimes described herein as an illustrative example. Glass layer 52 may form an outermost surface of display 14 and device 10. When display 14 has bare glass on its outer surface (e.g., without a protective polymer layer), care must be taken to ensure that objects impacting display 14 do not cause subsurface damage to cover layer 14CG such as median cracks, which can cause glass failure. Crack resistance may be increased by increasing the thickness of cover layer 14CG, but this may prevent cover layer 14CG from achieving the desired bending radius (e.g., a bending radius of 100 microns or less, as an example).

To maintain the desired bending radius while providing additional crack resistance, glass layer 52 of cover layer 14CG may have a thickness T of less than 200 microns (e.g., in bend region 62) and may exhibit a high crack initiation load such as a crack initiation load of at least 10 kgf (kilogram force), greater than 15 kgf, between 15 kgf and 20 kgf, between 20 kgf and 30 kgf, greater than 30 kgf, or less than 30 kgf. For example, layer 52 may be formed from glass (e.g., borosilicate glass, boro-aluminosilicate glass, alkali boroaluminosilicate glass, and/or other suitable glass compositions) that has a lower density of polymer chains when compared to traditional aluminosilicate glasses with crack initiation loads of less than 10 kgf. When the network of polymer chains is expanded in this way, sharp contact from external objects may compress the network of polymer chains (a process sometimes referred to as densification), thereby absorbing energy and suppressing median crack formation until a much higher load is applied (e.g., a load of 10 kgf or more).

In addition to using a glass composition that has a high crack initiation load, glass layer 52 may be formed with or without ion exchange. Even without using an ion exchange process to chemically strengthen the surface of glass layer 52, glass layer 52 may still exhibit better crack resistance when compared with glass compositions having crack initiation loads of less than 10 kgf. When glass layer 52 is formed with ion exchange, glass layer 52 may have compressive stress regions 82 at the opposing sides of glass layer 52. The compressive stress of regions 82 may be greater than 100 megapascals, greater than 200 megapascals, greater than 500 megapascals, or less than 500 megapascals. The depth-of-layer TD of compressive stress regions 82 may be 5 microns to 10 microns, 10 microns to 15 microns, 15 microns to 20 microns, greater than 20 microns, less than 20 microns, or other suitable depth-of-layer. The presence of compressive stress regions 82 in glass 52 may increase the amount of force required to cause glass 52 to fail.

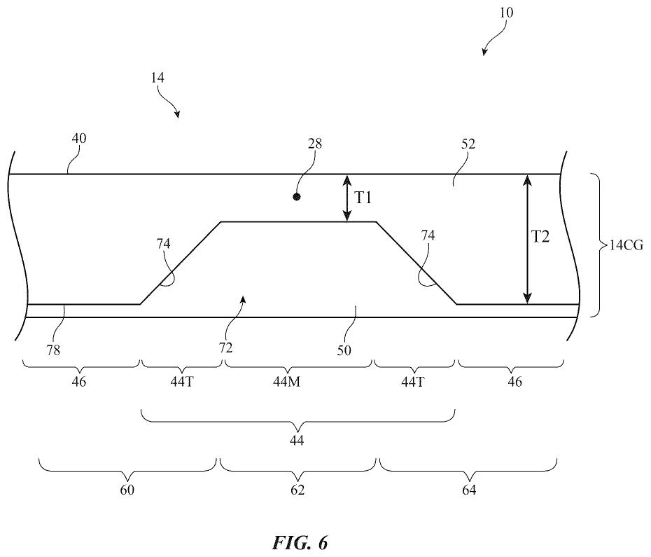

In the example of FIG. 5, glass layer 52 has a uniform thickness T across regions 60, 62, and 64. If desired, glass layer 52 may have a variable thickness to facilitate bending in region 62. This type of arrangement is illustrated in FIG. 6.

As shown in FIG. 6, glass layer 52 of display 14 has a variable thickness to facilitate bending of glass layer 52. In particular, cover layer 14CG may include a groove such groove 72 that overlaps and runs parallel to bend axis 28 to form a strip-shaped locally reduced thickness portion 44 in glass layer 52. Locally reduced thickness portion 44 of layer 52 may be thinner than other portions of layer 52 such as portions 46 (which may be, for example, planar glass portions of layer 52). Glass layer 52 may have a first thickness T1 in region 44M and a second thickness T2 in regions 46. Thickness T1 may be 50 microns to 100 microns, 100 microns to 200 microns, 75 microns to 150 microns, greater than 200 microns, or less than 200 microns. Thickness T2 may be 300 microns to 400 microns, 200 microns to 400 microns, greater than 400 microns, or less than 400 microns. The presence of reduced thickness portion 44 in glass layer 52 may facilitate bending of glass layer 52 about bend axis 28.

It may be desirable to configure the cross-sectional profile of glass layer 52 of display cover layer 14CG to help avoid distortion of the image on display panel 14P due to changes in the refraction of light from thickness variations in glass layer 52. As shown in FIG. 6, for example, glass layer 52 may include tapered edges such as tapered edges 74 on opposing sides of groove 72. Tapered edges 74 of glass layer 52 may form sloped sidewalls on opposing sides of groove 72 that provide locally reduced thickness region 44 of glass layer 52 with varying thickness portions 44T. Portions 44T may be tapered and characterized by smoothly and gradually varying thicknesses. Portions 44T may be located at the outer edges of locally reduced thickness region 44 and may provide layer 52 with a gradual transition between the thinnest part of layer 52 (e.g., portion 44M of portion 44 of layer 52, which forms part of bendable region 62 of display 14) and the thicker portions of layer 52 such as portions 46 (e.g., portions 46 of layer 52 which are located in first portion 60 and second portion 64 of display 14). By gradually changing the thickness of glass layer 52 from thickness T1 to thickness T2, undesired visual artifacts and stress concentration features may be avoided.

To provide a planar surface and thereby facilitate mounting of display panel 14P to cover layer 14CG, the elongated recess (groove) 72 in the inner surface of layer 52 that forms thinned portion 44 may be filled with a polymer such as polymer 50. Polymer 50 may be sufficiently flexible to bend about bend axis 28 when device 10 is opened and closed. The refractive index of polymer 50 may be matched to that of glass layer 52 to help minimize light reflections (e.g., by incorporating inorganic nanoparticles in polymer 50). For example, at a wavelength of 500 nm, the refractive index of polymer 50 may differ from that of layer 52 and/or layer 60 by less than 0.15, less than 0.1, or less than 0.05 (as examples). If desired, polymer 50 may be located only in groove 72 or may also be located on the lower surface of glass 52.

Glass layer 52 may exhibit a high crack initiation load such as a crack initiation load of greater than 10 kgf. In addition to using a glass composition that has a high crack initiation load, glass layer 52 may be formed with or without ion exchange. When glass layer 52 is formed with ion exchange, glass layer 52 may have compressive stress regions (e.g., similar to compressive stress regions 82 of FIG. 5) at the opposing sides of glass layer 52. The compressive stress of these regions may be greater than 100 megapascals, greater than 200 megapascals, greater than 500 megapascals, or less than 500 megapascals.

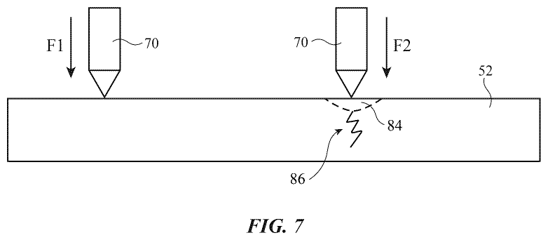

FIG. 7 is a side view of glass layer 52 showing how a Vickers indentation test may be used to determine the crack initiation load of glass layer 52. When a sharp object such as Vickers indenter 70 contacts glass with a given force, the composition of the glass will determine whether the glass exhibits shear deformation or densification in response to the sharp contact. These two competing mechanisms may have different effects on the glass. Glass compositions such as soda lime glass that include higher amounts of non-bridging oxygen content may have higher packing densities and may therefore tend to exhibit shear deformation in response to sharp contact. This type of shear deformation leads to high residual stress and subsurface damage such as median and radial cracks. In these types of glasses, the load required to cause cracks may be relatively low. On the other hand, glass compositions that have lower amounts of non-bridging oxygen content may tend to deform with volume reducing densification in response to sharp contact.

Glass 52 may be a damage resistant class such as alkali boroaluminosilicate glass that is free of alkaline earth oxides. Other glass compositions that exhibit crack initiation loads of greater than 10 kgf may be used for glass layer 52, if desired. FIG. 7 shows a Vickers indenter 70 being applied to glass 52 with different amounts of force such as force F1 and force F2. Force F1 may represent the crack initiation load (sometimes referred to as the cracking threshold) of glass 52. Force F1 may be equal to 10 kgf or other suitable cracking threshold, whereas force F2 may be greater than cracking threshold F1. For example, if F1 is equal to 10 kgf, F2 may be 11 kgf or other suitable force greater than 10 kgf. If desired, glass 52 may have a crack resistance threshold F1 that is greater than 10 kgf (e.g., force F1 may be equal to 11 kgf, 15 kgf, 20 kgf, 30 kgf, greater than 30 kgf, less than 30 kgf, or other suitable force). Vickers indenter 70 may not cause any cracks at force F1. When the force of the Vickers indenter 70 on glass 52 is increased beyond F1 (e.g., to force F2), scratch 84 may be formed in glass 52, resulting in median crack 86.

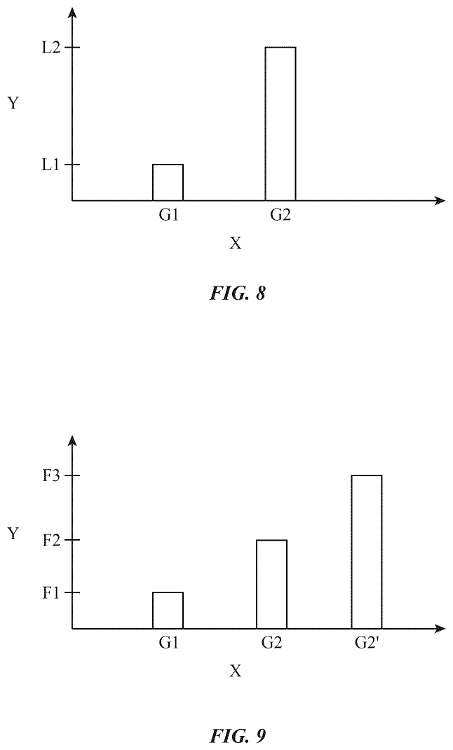

FIG. 8 is a graph showing how the crack initiation load of glass 52 may compare to other glasses. In the graph of FIG. 8, the X axis represents different glass compositions, and the Y axis represents different crack initiation loads. Glass G1 may be an alkali-aluminosilicate glass (or other glass with higher levels of non-bridging oxygen content and/or a greater tendency to exhibit shear deformation in response to sharp contact when compared to glass G2), whereas glass G2 may be an alkali boroaluminosilicate glass (or other glass with lower levels of non-bridging oxygen content than glass G1 and/or a greater tendency to exhibit densification in response to sharp contact when compared to glass G1).

Glasses G1 and G2 may have the same thickness and ion exchange condition but may exhibit different cracking thresholds due to the different compositions of glasses G1 and G2. Glass G1 may exhibit a crack initiation load of L1, whereas glass G2 may exhibit a crack initiation load of L2 (e.g., a load value greater than L1). Crack initiation load L1 of glass G1 may be less than 8 kgf, less than 6 kgf, less than 4 kgf, or other suitable load value. Crack initiation load L2 of glass G2 may be 10 kgf, 11 kgf, 15 kgf, 20 kgf, 30 kgf, greater than 30 kgf, or less than 30 kgf. By using glass composition G2 for glass layer 52, cover layer 14CG may exhibit better sharp damage resistance, which in turn allows glass 52 to form a bare glass surface of foldable display 14 (e.g., an exposed, bare glass surface on device 10 that is not covered with any protective polymer layers and that is also bendable in region 62).

FIG. 9 is a graph showing how different glass compositions and ion exchange conditions may exhibit different force-to-failure values under the Knoop scratch test. In the graph of FIG. 9, the X axis represents different glass compositions and ion exchange conditions, and the Y axis represents different Knoop scratch test force-to-failure values. Similar to the Vickers indentation test, the Knoop scratch test uses an indenter to apply sharp contact to glass with different amounts of force. Glass G1 may be an alkali-aluminosilicate glass (or other glass with higher levels of non-bridging oxygen content and/or a greater tendency to exhibit shear deformation in response to sharp contact when compared to glass G2), whereas glass G2 may be an alkali boroaluminosilicate glass (or other glass with lower levels of non-bridging oxygen content than glass G1 and/or a greater tendency to exhibit densification in response to sharp contact when compared to glass G1). Glass G1 may be formed with an ion exchange process. Glass G2′ may be the same glass composition as glass G2, but glass G2 is without ion exchange and glass G2′ is with ion exchange. Glasses G1, G2, and G2′ may have the same thickness but may exhibit different force-to-failure values due to the different compositions of the different glasses and the different ion exchange conditions of the glasses. Force-to-failure value F1 of glass G1 may be less than 6 newtons (N), less than 5 N, less than 4 N, or other suitable force value. Force-to-failure value F2 of glass G2 may be less than 8 N, less than 7 N, between 4 N and 8 N, or other suitable force value. Force-to-failure value F3 of glass G2′ may be less than 12 N, less than 11 N, more than 8 N, more than 10 N, between 6 N and 12 N, or other suitable force value. By using glass G2 or glass G2′ for glass layer 52, cover layer 14CG may exhibit better sharp damage resistance, which in turn allows glass 52 to form a bare glass surface of foldable display 14 (e.g., an exposed, bare glass surface on device 10 that is not covered with any protective polymer layers and that is also bendable in region 62).

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made to the described embodiments. The foregoing embodiments may be implemented individually or in any combination.

What is claimed is:

1. A foldable electronic device, comprising:
a display panel having first and second display regions that fold relative to one another about an axis; and
a layer of glass that overlaps the first and second display regions and the axis, wherein the layer of glass forms an exposed outer surface of the foldable electronic device and exhibits a crack initiation load of at least 10 kgf.

2. The foldable electronic device defined in claim 1 wherein the layer of glass has first and second portions that respectively overlap the first and second display regions and that are joined by a bendable portion, wherein the bendable portion has a first thickness and the first and second display regions have a second thickness that is greater than the first thickness.

3. The foldable electronic device defined in claim 2 wherein the first thickness is less than 200 microns.

4. The foldable electronic device defined in claim 2 wherein the bendable portion of the layer of glass has a groove that aligns with and extends parallel to the axis.

5. The foldable electronic device defined in claim 4 wherein the layer of glass has sloped sidewalls on opposing sides of the groove.

6. The foldable electronic device defined in claim 4 further comprising a transparent polymer in the groove.

7. The foldable electronic device defined in claim 6 wherein transparent polymer covers a lower surface of the first and second portions of the layer of glass.

8. The foldable electronic device defined in claim 1 wherein the layer of glass comprises alkali boroaluminosilicate glass.

9. The foldable electronic device defined in claim 1 wherein the layer of glass comprises a compressive stress region exhibiting a compressive stress of at least 100 MPa.

10. The foldable electronic device defined in claim 1 further comprising an adhesive layer that attaches the layer of glass to the display panel.

11. A foldable display, comprising:
a flexible display panel that bends along a bend axis; and
a cover glass that overlaps the flexible display panel, wherein the cover glass has a bendable region aligned with the bend axis, wherein a thickness of the bendable region is less than 200 microns, and wherein the cover glass exhibits a crack initiation load of at least 10 kgf.

12. The foldable display defined in claim 11 wherein the cover glass has first and second portions that fold relative to one another about the bend axis and wherein the thickness of the bendable region is less than a thickness of the first and second portions.

13. The foldable display defined in claim 11 wherein the cover glass comprises a compressive stress region exhibiting a compressive stress of at least 100 MPa.

14. The foldable display defined in claim 11 wherein the cover glass comprises a groove aligned with the bend axis and filled with a transparent polymer.

15. The foldable display defined in claim 11 wherein the cover glass forms a bare glass outer surface of the foldable display.

16. A display, comprising:
a display panel having first and second display regions that rotate relative to one another about an axis; and
a cover layer through which the foldable display presents images, wherein the cover layer comprises a glass layer having a first portion that overlaps the first display region, a second portion that overlaps the second display region, and a bendable portion that joins the first and second portions, and wherein the glass layer exhibits a crack initiation load of at least 10 kgf.

17. The display defined in claim 16 wherein the bendable region has a first thickness and the first and second portions have a second thickness that is greater than the first thickness.

18. The display defined in claim 17 wherein the first thickness is less than 200 microns.

19. The display defined in claim 16 wherein the glass layer forms an exposed glass surface on the display.

20. The display defined in claim 16 wherein the glass layer comprises a compressive stress region exhibiting a compressive stress of at least 100 MPa.
